(19) United States
(12) Patent Application Publication
(10) Pub. No.: US 2023/0238939 A1
(43) Pub. Date: Jul. 27, 2023

(54) SURFACE ACOUSTIC WAVE RESONATORS

(71) Applicant: Skyworks Solutions, Inc., Irvine, CA (US)

(72) Inventor: Akira Ochiai, Suita-Shi (JP)

(21) Appl. No.: 18/156,320

(22) Filed: Jan. 18, 2023

Related U.S. Application Data
(60) Provisional application No. 63/300,927, filed on Jan. 19, 2022.

(51) Int. Cl. H03H 9/64; H03H 9/56; H03H 9/145; H03H 9/76

(52) U.S. Cl. CPC H03H 9/6483; H03H 9/76; H03H 9/568; H03H 9/14502; H03H 9/14544

(57) ABSTRACT

Disclosed herein are embodiments of a ladder-type filter comprising a plurality of series arm resonators and a plurality of parallel arm resonators, at least one of the plurality of series arm resonators including a piezoelectric substrate and an interdigital transducer electrode disposed on the piezoelectric substrate, an aperture W1 of the interdigital transducer electrode being configured to be less than 13λ, where λ is a wavelength of a surface acoustic wave excited by the interdigital transducer electrode. The relationship between the aperture W1 and the wavelength λ can be W1 < 13λ, W1 < 11λ, W1 < 4λ, or W1 > 6λ.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

Embodiments of this disclosure relates to surface acoustic wave (SAW) resonators. An acoustic wave filter can include a plurality of resonators arranged to filter a radio frequency. Examples of such acoustic wave filters can include surface acoustic wave (SAW) filters and bulk acoustic wave (BAW) filters. A SAW resonator can include an interdigital transducer (IDT) electrode on a piezoelectric substrate. Such a SAW resonator can generate a surface acoustic wave on a surface of the piezoelectric substrate on which the IDT electrode is disposed.

Acoustic wave filters can be implemented in a radio frequency system. For instance, filters in a radio frequency front end of a mobile phone can include acoustic wave filters. Such an acoustic wave filter can be a band pass filter. A plurality of acoustic wave filters can be arranged as a multiplexer. For instance, two acoustic wave filters can be arranged as a duplexer.

### SUMMARY OF CERTAIN INVENTIVE ASPECTS

Disclosed herein are embodiments of a surface acoustic wave resonator comprising a piezoelectric substrate and an interdigital transducer electrode disposed on the piezoelectric substrate, in which a region where electrode fingers of an interdigital transducer (IDT) electrode are overlapped with each other (referred to as aperture hereinafter) can be smaller than 13λ, where λ is a wavelength of a surface acoustic wave excited by the IDT electrode. The aperture can be smaller than 11λ, greater than 4λ, and greater than 6λ.

The IDT electrode can excite the surface acoustic wave having the wavelength λ on the piezoelectric substrate in a piston mode.

Disclosed herein are embodiments of an acoustic wave filter, which can be a ladder-type acoustic wave filter comprising a plurality of series arm resonators and a plurality of parallel arm resonators, and at least one of the plurality of series arm resonators is the surface acoustic wave resonator as described above.

Disclosed herein are embodiments of an acoustic wave filter assembly comprising a first acoustic wave filter coupled to a common node and a second acoustic wave filter connected to the common node, and at least one of the first and second acoustic wave filters is the acoustic wave filter configured as described above. The acoustic wave filter assembly can further include a third acoustic wave filter coupled to the common node and a fourth acoustic wave filter connected to the common node.

Disclosed herein are embodiments of a wireless communication device comprising an antenna and a multiplexer coupled to the antenna, and the multiplexer includes a plurality of filters coupled to a common node and arranged to filter a radio frequency signal, and at least one of the plurality of filters is the acoustic wave filter as described above.

### BRIEF DESCRIPTION OF THE DRAWINGS

Embodiments of this disclosure will now be described, by way of non limiting example, with reference to the accompanying drawings.

FIG. 1A is a plan view of a surface acoustic wave resonator according to an embodiment.

FIG. 1B is a cross sectional view of a surface acoustic wave resonator according to an embodiment.

FIG. 2A is a plan view showing a schematic configuration of an IDT electrode for an acoustic wave resonator according to an embodiment.

FIG. 2B is a plan view showing a schematic configuration of an IDT electrode for an acoustic wave resonator according to a comparative example.

FIG. 3 is a circuit diagram of a surface acoustic wave filter according to an embodiment.

FIGS. 4A to 4D are graphs showing examples of admittance versus frequency for a first series arm resonator.

FIGS. 5A to 4D are graphs showing examples of admittance versus frequency for a second series arm resonator.

FIGS. 6A to 6D are graphs showing examples of admittance versus frequency for a third series arm resonator.

FIGS. 7A to 7D are graphs showing examples of admittance versus frequency for a fourth series arm resonator.

FIG. 8A is a schematic diagram of a duplexer including a surface acoustic wave filter according to an embodiment.

FIG. 8B is a schematic diagram of a multiplexer including a surface acoustic wave filter according to an embodiment.

FIG. 9A is a plan view of a multi-band surface acoustic wave filter according to an embodiment.

FIG. 9B is a plan view of a multi-band surface acoustic wave filter according to a comparative example.

FIGS. 10A to 10E are graphs showing examples of insertion loss versus frequency of the multi-band surface acoustic wave filters shown in FIGS. 9A and 9B.

FIG. 11 is a schematic diagram of a radio frequency module including a surface acoustic wave filter according to an embodiment.

FIG. 12 is a schematic diagram of a radio frequency module including an antenna switch and a duplexer according to an embodiment.

FIG. 13 is a schematic diagram of a radio frequency module including a power amplifier, a radio frequency switch, and a duplexer according to an embodiment.

FIG. 14 is a schematic diagram of a radio frequency module including a surface acoustic wave filter according to an embodiment.

FIG. 15A is a schematic block diagram of a wireless communication device including a surface acoustic wave filter according to an embodiment.

FIG. 15B is a schematic block diagram of another wireless communication device including a surface acoustic wave filter according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

### Surface Acoustic Wave Resonators

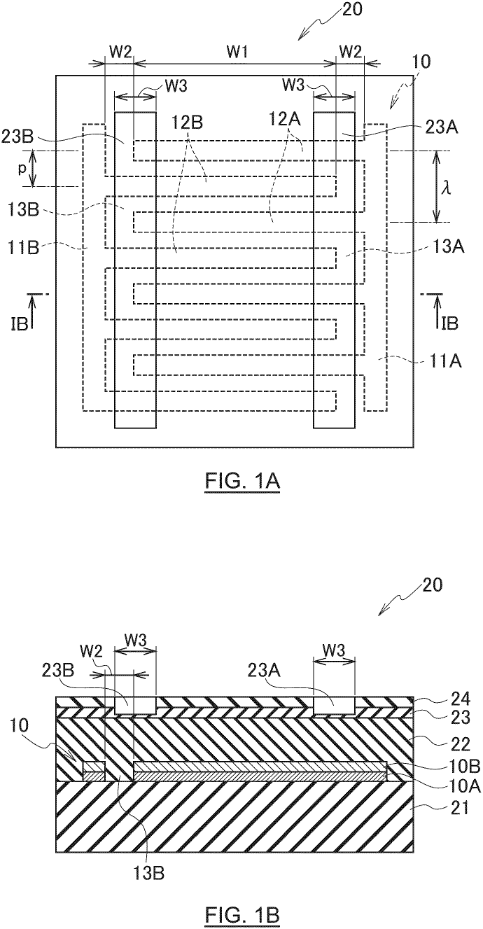

FIG. 1A is a plan view of a surface acoustic wave resonator 20 according to an embodiment. FIG. 1B is a cross sectional view of the surface acoustic wave resonator 20 according to an embodiment. The cross sectional view of FIG. 1B shows a cross section taken along the lines IB-IB in the plan view of FIG. 1A. The surface acoustic wave resonator 20 includes an interdigital transducer (IDT) electrode 10 disposed on a top surface of a piezoelectric substrate 21 such as a 128° Y-cut lithium niobate (LiNbO₃) (also referred to as LN) monocrystalline layer. The material of the substrate 21 is not limited to lithium niobate but may also include another type of piezoelectric material such as tantalum niobate (LiTaO₃) (also referred to as LT) and may also have another cut angle.

The IDT electrode 10 includes first and second bus bars 11A and 11B that extend in a propagation direction of a surface acoustic wave and are arranged to oppose each other separated by a gap, and first and second electrode fingers 12A and 12B that extend from the first and second bus bars 11A and 11B, respectively, to the opposite second and first bus bars 11B and 11A, respectively. The first and second electrode fingers 12A and 12B are arranged in parallel with each other by a pitch p in the propagation direction of the surface acoustic wave. The first and second electrode fingers 12A and 12B have respective tips opposing the second and first bus bars 11B and 11A, respectively, by second and first gaps 13B and 13A, respectively. A main surface acoustic wave excited by the IDT electrode 10 has a wavelength λ (also referred to as wavelength λ of the IDT electrode 10), which is configured to be twice the pitch p between the first electrode finger 12A and the second electrode finger 12B. Each of the first and second gaps 13A and 13B is configured to be a width W2 in a direction in which the respective electrode fingers extend. A region where the first electrode fingers 12A overlap with the second electrode fingers 12B in a direction perpendicular to the propagation direction of the surface acoustic wave is configured to have a width of an aperture W1. The IDT electrode 10 is formed by stacking a first metal layer 10A such as a molybdenum layer and a second metal layer 10B such as an aluminum layer sequentially.

A temperature compensation layer 22 formed from silicon dioxide (SiO₂) is disposed on the top surface of the substrate 21 to have a height and cover the IDT electrode 10. The temperature compensation layer 22 can compensate a frequency-temperature characteristic represented by a temperature coefficient of frequency (TCF) originated from the substrate 21 to improve the frequency-temperature characteristic of the surface acoustic wave resonator 20. Furthermore, a first passivation layer 23 formed from silicon nitride (SiN) and a second passivation layer 24 formed from silicon oxynitride (SiON) are sequentially stacked on a top surface of the temperature compensation layer 22. The first and second passivation layers 23 and 24 include first and second trenches 23A and 23B forming recesses that extend through the second passivation layer 24 and penetrate to a certain depth of the first passivation layer 23 and also extend parallel to each other in the propagation direction of the surface acoustic wave. The recesses each have a width region W3. The first and second trenches 23A and 23B overlap with tips of the second and first electrode fingers 12B and 12A, respectively, in respective width regions W3. The first and second trenches 23A and 23B extending in the propagation direction can confine excitation energy of the surface acoustic wave within a region sandwiched between the first trench 23A and the second trench 23B to suppress a generation of a spurious acoustic wave.

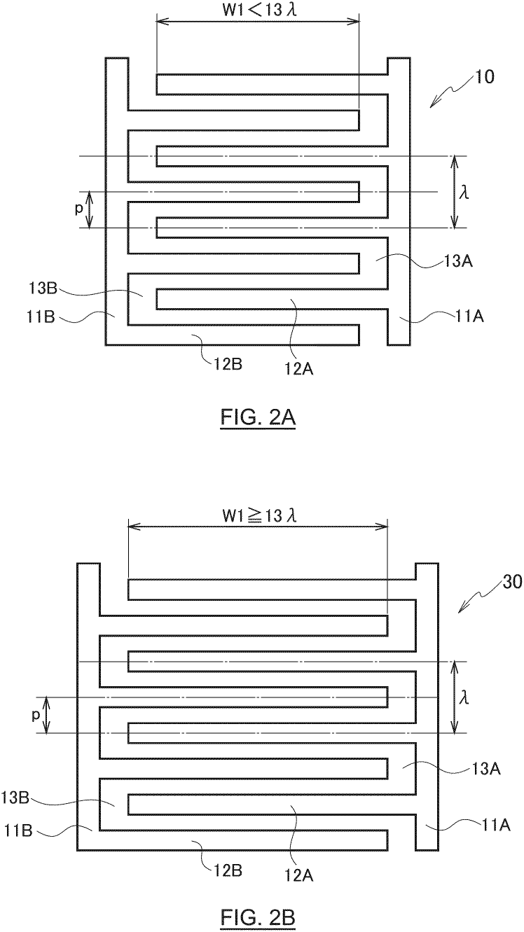

FIG. 2A is a plan view showing a schematic configuration of the IDT electrode 10 of the surface acoustic wave resonator 20. The IDT electrode 10 includes the first electrode fingers 12A extending from the first bus bar 11A and the second electrode fingers 12B extending from the second bus bar 11B opposing the first bus bar 11A. As described above, the wavelength λ of the IDT electrode 10 is configured to be twice the pitch p between the first electrode finger 12A and the second electrode finger 12B. The aperture W1 is a width of the region of the IDT electrode 10 where the first electrode fingers 12A overlap with the second electrode fingers 12B in a direction perpendicular to the propagation direction of the surface acoustic wave. In the surface acoustic wave resonator 20 according to an embodiment, the relationship between the wavelength λ and the aperture W1 of the IDT electrode 10 can be W1 < 13λ, and also can be W1 < 11λ. Further, the relationship can be W1 > 4λ, and can be W1 > 6λ.The relationship of W1 < 13λ is defined as an upper limit of the aperture W1 according to an embodiment such that the aperture W1 can be smaller than a prior art aperture. The relationship of W1 < 11λ is defined based on experiments described below in which a preferable frequency characteristic was obtained comparable to the prior art when the aperture W1 equals to 10λ. Further, the relationship of W1 > 4λ or W1 > 6λ is defined as a lower limit of the aperture W1 by which a preferable frequency characteristic was obtained in consideration of the results from the experiments described below that the relationship of W1 = 3λ generated a spurious acoustic wave and caused the electromechanical coupling coefficient to be smaller and that the relationship of W1 = 5λ generated a spurious acoustic wave.

FIG. 2B is a plan view showing a schematic configuration of a comparative example IDT electrode 30 in the surface acoustic wave resonator 20. The comparative example IDT electrode 30 can pertain to a prior art IDT electrode. The comparative example IDT electrode 30 shown in FIG. 2B is similar to the IDT electrode 10 shown in FIG. 2A in terms of the wavelength λ of the main surface acoustic wave and the aperture W1. The comparative example IDT electrode 30 is configured such that the relationship between the wavelength λ and the aperture W1 can be W1 ≥ 13λ. This relationship is based on the experiment results described below that the aperture W1 of the prior art IDT electrode 30 was 13.5λ or greater.

The IDT electrode 10 shown in FIG. 2A is different from the comparative example IDT electrode 30 shown in FIG. 2B in that the aperture W1 of the IDT electrode 10 is configured to satisfy the relationship of W1 < 13λ whereas the aperture W1 of the comparative example IDT electrode 30 is configured to satisfy the relationship of W1 ≥ 13λ. According to an embodiment, the aperture W1 of the IDT electrode 10 is configured to be so small as less than 13λ that the surface acoustic wave resonator 20 including such an IDT electrode 10 and thus the acoustic wave filter including such a surface acoustic wave resonator 20 can be downsized. In addition, the downsized surface acoustic wave resonator 20 of this embodiment can shorten a path extending between an input node and an output node and accordingly the insertion loss can be improved.

### Surface Acoustic Wave Filters

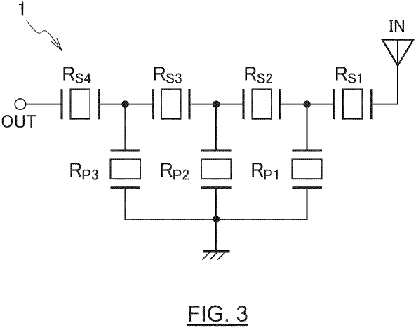

FIG. 3 is a circuit diagram of a surface acoustic wave (SAW) filter 1 according to an embodiment. The surface acoustic wave filter 1 is configured as a ladder-type filter as a whole, in which first to fourth series arm surface acoustic wave resonators R_{S1} to R_{S4} are arranged at respective series arms that extend from an antenna or input node IN to an output node OUT and first to third parallel arm surface acoustic wave resonators R_{P1} to R_{P3} are arranged at respective parallel arms, each of which connects a node between respective series arm nodes and a reference potential such as a ground. Each of the first to fourth series arm surface acoustic wave resonators R_{S1} to R_{S4} is configured as the surface acoustic wave resonator 20 shown in FIG. 2A according to an embodiment. Thus, the first to fourth series arm surface acoustic wave resonators R_{S1} to R_{S4} are configured such that the relationship between the aperture W1 and the wavelength λ of the IDT electrode 10 can be W1 <, W1 <, W1 <, or W1 < .It should be appreciated that, although each of the first to fourth series arm surface acoustic wave resonators R_{S1} to R_{S4} is configured as the surface acoustic wave resonator 20 as described above, at least one of the first to fourth series arm surface acoustic wave resonators R_{S1} to R_{S4} can be configured as the surface acoustic wave resonator 20. The surface acoustic wave filter 1 can be applied not only to the downlink band frequency ranging from 2620 MHz to 2690 MHz of Band 7 according to the Long Term Evolution (LTE) standard, but also to the uplink band frequency of Band 7, and to other band frequencies such as Band 25 (B25), Band 30 (B30), Band 53 (B53), Band 66 (B66), and Band 70 (B70).

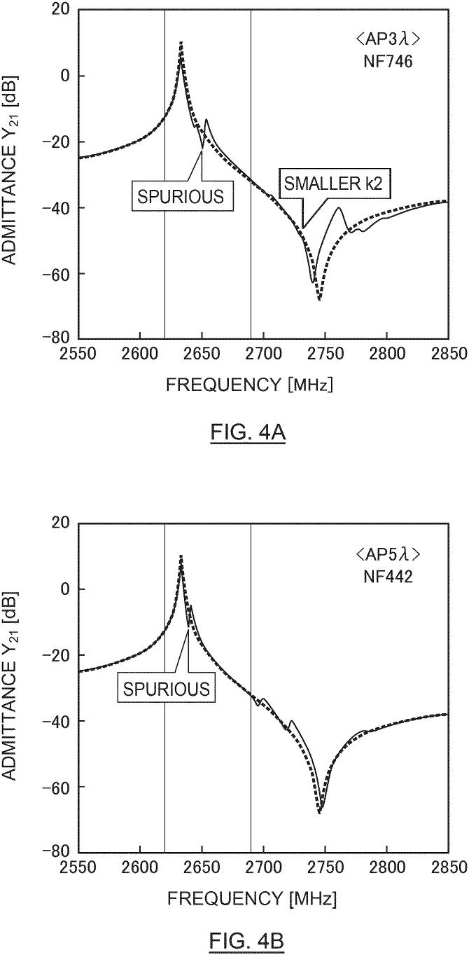

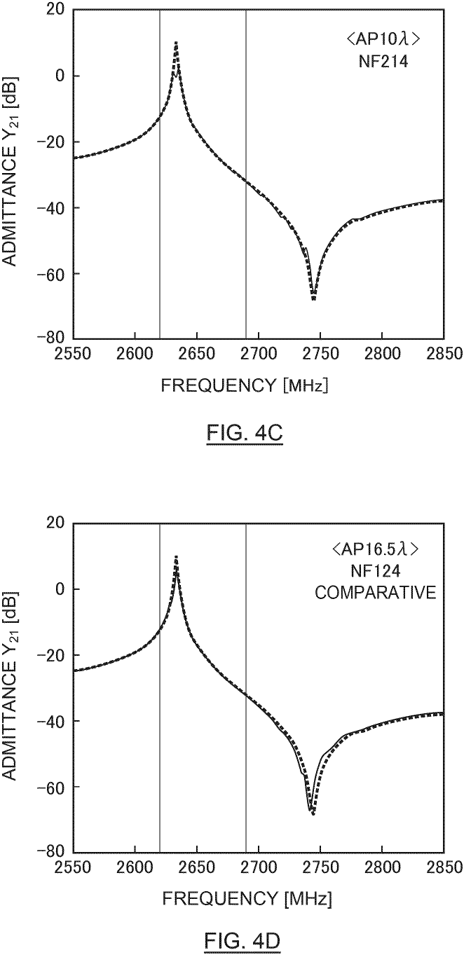

FIGS. 4A to 4C are graphs comparing admittance Y₂₁ versus frequency measurement results with simulation results of the first series arm surface acoustic wave resonator R_{S1}. In the drawings, solid lines represent measurement results and dashed lines represent simulation results. The measurement results were obtained by measuring a test element group (TEG) and the simulation results were obtained by creating an equivalent circuit model of the first series arm surface acoustic wave resonator R_{S1} and deriving a simplified evaluation of frequency characteristics for the equivalent circuit model based on the theory of alternating currents. Noise figures (NFs) in the simulations were derived from an equation including parameters such as: a position of the first series arm surface acoustic wave resonator R_{S1} in the surface acoustic wave filter 1; the aperture W1 of the IDT electrode 10; the width W2 of the first and second gaps 13A and 13B; the width W3 of the first and second trenches 23A and 23B; and the wavelength λ of the IDT electrode 10. In the measurements, the logarithmic NFs of the IDT electrode 10 were adjusted to the changes of the aperture W1 such that the comparison was to be based on a constant capacitance of the first series arm surface acoustic wave resonator R_{S1}. The same applies to the simulations described below. Accordingly, such simulations provided an ideal frequency characteristic that was originated from the piston mode oscillation in the main surface acoustic wave of the first series arm surface acoustic wave resonator R_{S1}, and such measurements provided an actual frequency characteristic that was further originated from an oscillation such as a spurious oscillation other than the piston mode oscillation. A band frequency between 2620 MHz and 2690 MHz for the downlink of the Band 7 (B7) according to the LTE standard was applied to the simulations and the measurements. The same applies to the simulations and the measurements shown in FIGS. 4D, 5A to 5D, 6A to 6D, and 7A to 7D.

Similar to the configuration of the surface acoustic wave resonator 20 shown in FIGS. 1A and 1B, the width W3 of each of the first and second trenches 23A and 23B was 1λ and the width W2 of each of the first and second gaps 13A and 13B was 1.5λ in the examples of FIGS. 4A to 4C. FIG. 4A shows an example in which the aperture W1 of the IDT electrode 10 was 3λ and the NF was 746 dB. According to the measurement results, a spurious component was observed in the band frequency and the electromechanical coupling coefficient k2 was observed smaller than that of the simulation results due to the suppression of a decrease in the admittance Y₂₁. Thus, the frequency characteristic of this example was regarded as involving a relatively greater contribution by a spurious oscillation other than the piston mode oscillation. FIG. 4B shows an example in which the aperture W1 was 5λ and the NF was 442 dB. Since NFs depend on parameters including the aperture W1 and the like as described above, the NF of the example shown in FIG. 4B was different from the NF of the example shown in FIG. 4A in which the aperture W1 was 3λ. According to the measurement results, a spurious component was observed in the band frequency. FIG. 4C shows measurement results obtained by an example of the aperture W1 = 10λ and the NF = 214 dB. According to the measurement results, no spurious component was observed in the band frequency.

FIG. 4D is a graph obtained according to a comparative example surface acoustic wave resonator configured similar to the surface acoustic wave resonator 20 shown in FIGS. 1A and 1B. In this comparative example, the aperture W1 of the IDT electrode 10 was 16.5λ and the NF was 124 dB. In this comparative example, the configurations and conditions other than those specifically described were similar to those of the first series arm surface acoustic wave resonator R_{S1} of the embodiments shown in FIGS. 4A to 4C. According to the measurement results of this comparative example, no spurious component was observed in the band frequency. Comparing the measurement results of the example shown in FIGS. 4A to 4C with the measurement results of the comparative example shown in FIG. 4D, the example shown in FIG. 4C in which the aperture W1 was 10λ was observed to provide a preferable frequency characteristic including no spurious component in the band frequency, similar to the frequency characteristic of the comparative example. Thus, the first series arm surface acoustic wave resonator R_{S1} of the embodiment was observed when the aperture W1 was 10λ or greater to provide a preferable frequency characteristic including no spurious component similar to the comparative example pertaining to the prior art.

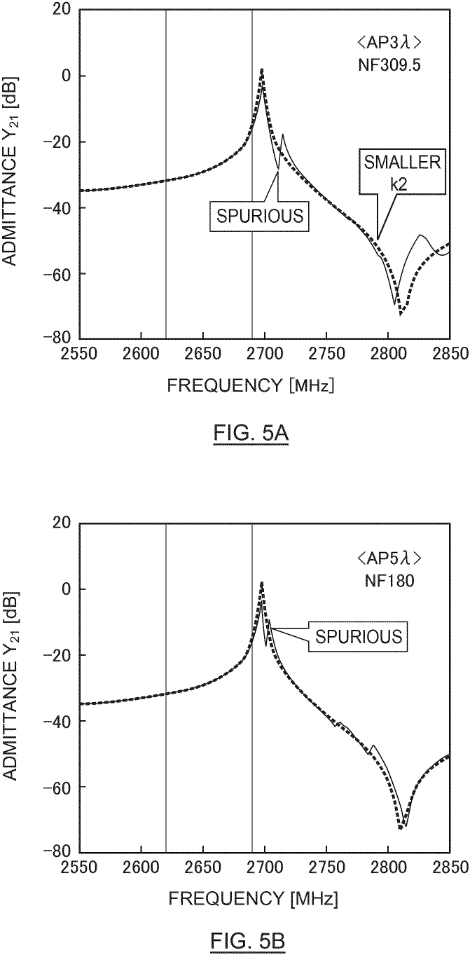

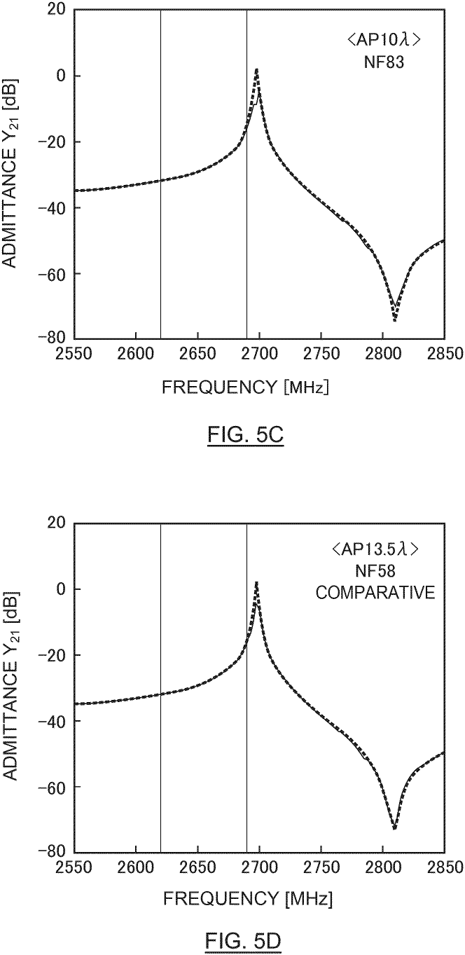

FIGS. 5A to 5C are graphs comparing admittance Y21 versus frequency measurement results with simulation results of the second series arm surface acoustic wave resonator RS2. Similar to the configuration of the surface acoustic wave resonator 20 shown in FIGS. 1A and 1B, the width W3 of each of the first and second trenches 23A and 23B was 1λ and the width W2 of each of the first and second gaps 13A and 13B was 1.5λ in the examples of FIGS. 5A to 5C. FIG. 5A shows measurement results obtained by an example of the aperture W1 = 3λ and the NF = 305.9 dB. According to the measurement results, a spurious component was observed in a passing signal in the band frequency and the electromechanical coupling coefficient k2 was smaller than that of the simulation results because the reduction of admittance Y21 was suppressed at the anti-resonant point. FIG. 5B shows measurement results obtained by an example of the aperture W1 = 5λ and the NF = 180 dB. According to the measurement results, a spurious component was observed in the band frequency. FIG. 5C shows measurement results obtained by an example of the aperture W1 = 10λ and the NF = 83 dB. According to the measurement results, no spurious component was observed in the band frequency.

FIG. 5D is a graph obtained according to a comparative example surface acoustic wave resonator configured similar to the surface acoustic wave resonator 20 shown in FIGS. 1A and 1B. In this comparative example, the aperture W1 of the IDT electrode 10 was 13.5λ and the NF was 58 dB. In this comparative example, the configurations and conditions other than those specifically described were similar to those of the second series arm surface acoustic wave resonator R_{S2} of the embodiments shown in FIGS. 5A to 5C. According to the measurement results of this comparative example, no spurious component was observed in the band frequency. Comparing the measurement results of the second series arm surface acoustic wave resonator R_{S2} shown in FIGS. 5A to 5C with the measurement results of the comparative example shown in FIG. 5D, the example shown in FIG. 5C in which the aperture W1 was 10λ was observed to provide a preferable frequency characteristic including no spurious component in the band frequency, similar to the frequency characteristic of the comparative example. Thus, the second series arm surface acoustic wave resonator R_{S2} of the embodiment was observed when the aperture W1 was 10λ or greater to provide a preferable frequency characteristic including no spurious component similar to the comparative example pertaining to the prior art.

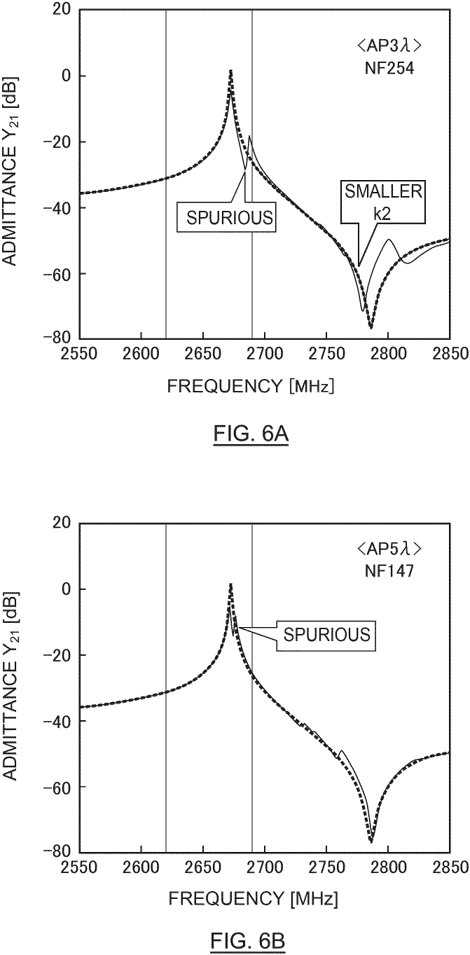

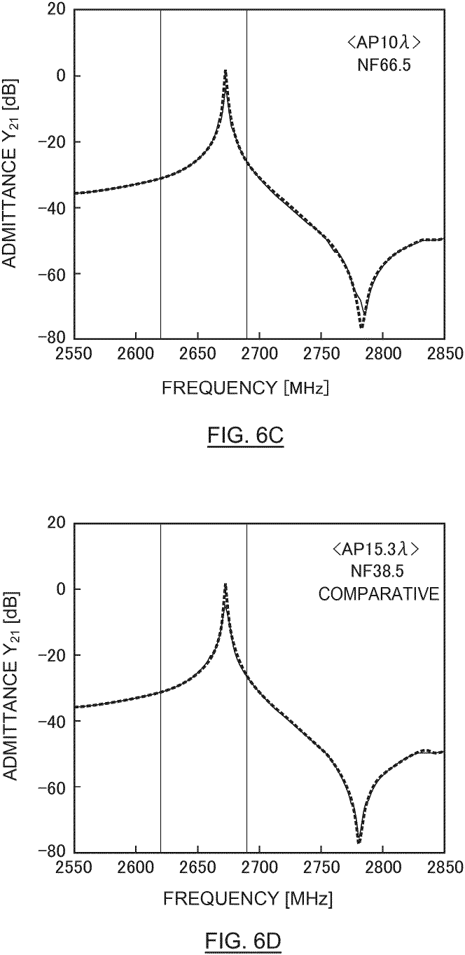

FIGS. 6A to 5C are graphs comparing admittance Y₂₁ versus frequency measurement results with simulation results of the third series arm surface acoustic wave resonator R_{S3} of an embodiment. Similar to the configuration of the surface acoustic wave resonator 20 shown in FIGS. 1A and 1B, the width W3 of each of the first and second trenches 23A and 23B was 1λ and the width W2 of each of the first and second gaps 13A and 13B was 1.5λ in the examples of FIGS. 6A to 6C. FIG. 6A shows measurement results obtained by an example of the aperture W1 = 3λ and the NF = 254 dB. According to the measurement results, a spurious component was observed in a passing signal in the band frequency and the electromechanical coupling coefficient k2 was smaller than that of the simulation results because the reduction of admittance Y₂₁ was suppressed at the anti-resonant point. FIG. 6B shows measurement results obtained by an example of the aperture W1 = 5λ and the NF = 147 dB. The measurement results indicated a spurious component in the band frequency. FIG. 6C shows measurement results obtained by an example of the aperture W1 = 10λ and the NF = 66.5 dB. The measurement results indicated no spurious component in the band frequency.

FIG. 6D is a graph obtained according to a comparative example surface acoustic wave resonator configured similar to the surface acoustic wave resonator 20 shown in FIGS. 1A and 1B. In this comparative example, the aperture W1 of the IDT electrode 10 was 15.3λ and the NF was 38.5 dB. In this comparative example, the configurations and conditions other than those specifically described were similar to those of the third series arm surface acoustic wave resonator R_{S3} of the embodiments shown in FIGS. 6A to 6C. According to the measurement results of this comparative example, no spurious component was observed in the band frequency. Comparing the measurement results of the example shown in FIGS. 6A to 6C with the measurement results of the comparative example shown in FIG. 6D, the example shown in FIG. 6C in which the aperture W1 was 10λ was observed to provide a preferable frequency characteristic including no spurious component in the band frequency, similar to the frequency characteristic of the comparative example. Thus, the third series arm surface acoustic wave resonator R_{S3} of the embodiment was observed when the aperture W1 was 10λ or greater to provide a preferable frequency characteristic including no spurious component, similar to the comparative example pertaining to the prior art.

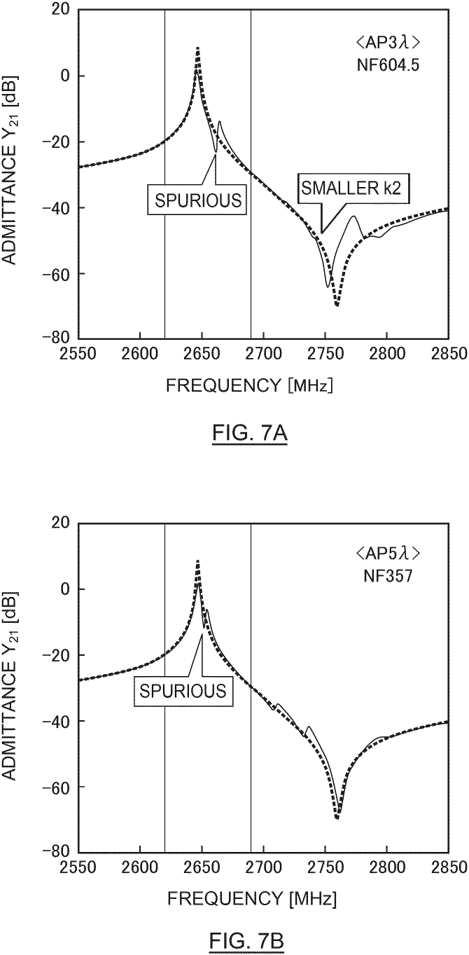

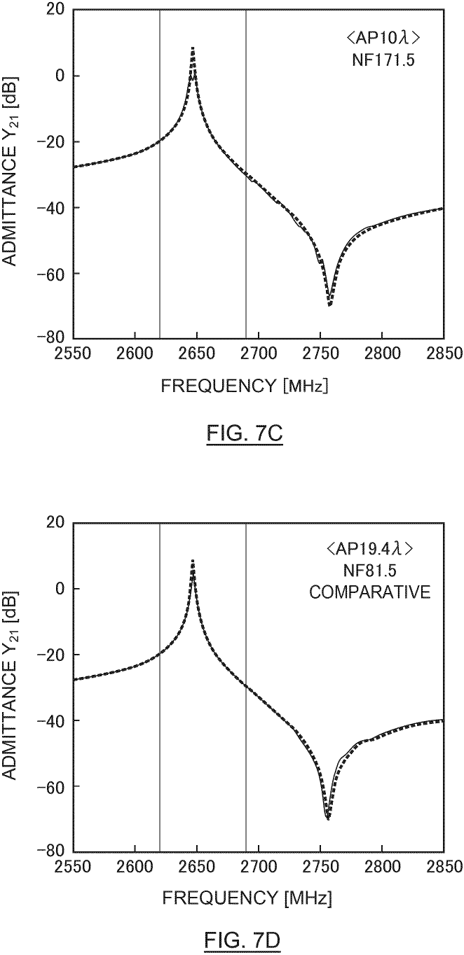

FIGS. 7A to 7C are graphs comparing admittance Y₂₁ versus frequency measurement results with simulation results of the fourth series arm surface acoustic wave resonator R_{S4} of an embodiment. Similar to the configuration of the surface acoustic wave resonator 20 shown in FIGS. 1A and 1B, the width W3 of each of the first and second trenches 23A and 23B was 1λ and the width W2 of each of the first and second gaps 13A and 13B was 1.5λ in the examples of FIGS. 7A to 7C. FIG. 7A shows measurement results obtained by an example of the aperture W1 = 3λ and the NF = 604.5 dB. According to the measurement results, a spurious component was observed in a passing signal in the band frequency and the electromechanical coupling coefficient k2 was smaller than that of the simulation results because the reduction of admittance Y₂₁ was suppressed at the anti-resonant point. FIG. 7B shows measurement results obtained by an example of the aperture W1 = 5λ and the NF = 357 dB. According to the measurement results, a spurious component was observed in the band frequency. FIG. 7C shows measurement results obtained by an example of the aperture W1 = 10λ and the NF = 171.5 dB. According to the measurement results, no spurious component was observed in the band frequency.

FIG. 7D is a graph obtained according to a comparative example surface acoustic wave resonator configured similar to the surface acoustic wave resonator 20 shown in FIGS. 1A and 1B. In this comparative example, the aperture W1 of the IDT electrode 10 was 19.4λ, and the NF was 81.5 dB. In this comparative example, the other configurations and conditions were similar to those of the fourth series arm surface acoustic wave resonator R_{S3} of the embodiments shown in FIGS. 7A to 7C. According to the measurement results of this comparative example, no spurious component was observed in the band frequency. Comparing the measurement results of the fourth series arm surface acoustic wave resonator R_{S4} shown in FIGS. 7A to 7C with the measurement results of the comparative example shown in FIG. 7D, the example shown in FIG. 7C in which the aperture W1 was 10λ was observed to provide a preferable frequency characteristic including no spurious component in the band frequency, similar to the frequency characteristic of the comparative example. Thus, the fourth series arm surface acoustic wave resonator R_{S4} of the embodiment was observed when the aperture W1 was 10λ or greater to provide a preferable frequency characteristic including no spurious component, similar to the comparative example pertaining to the prior art.

The measurement results shown in FIGS. 4A to 4C, FIGS. 5A to 5C, FIGS. 6A to 6C, and FIGS. 7A to 7C for the TEG indicated that the aperture W1 = 3λ caused a spurious component in the pass band and a smaller electromechanical coupling coefficient k2 and also the aperture W1 = 5λ caused a spurious component in the pass band. In consideration of the measurement results described above, a range of the aperture W1 allowing a preferable frequency characteristic can be defined as a range exceeding 4λ to exclude W1 = 3λ in which a spurious component and a smaller electromechanical coupling coefficient k2 were observed. Further, a range of the aperture W1 allowing a more preferable frequency characteristic can be defined as a range exceeding 6λ so as to exclude W1 = 5λ in which a small electromechanical coupling coefficient k2 was not observed but a spurious component was observed. Accordingly, the lower limit of the range allowing such a preferable frequency characteristic can be defined as W1 > 4λ or W1 > 6λ.

In the comparative examples pertaining to the prior art as shown in FIGS. 4D, 5D, 6D and 7D, the aperture W1 ranged from 13.5λ to 19.4λ. Accordingly, the range of the aperture W1 of an embodiment that can be smaller than the aperture of the comparative examples pertaining to the prior art can be defined as less than 13λ. On the other hand, the measurement results of an embodiment indicated that a preferable frequency characteristic similar to the measurement results of the comparative examples pertaining the prior art was obtained when the aperture W1 = 10λ. Thus, such a preferable frequency characteristic can be obtained in the range of the aperture W1 that includes 10λ and can be less than 11λ, for example. Consequently, the upper limit of the range allowing such a preferable frequency characteristic can be defined as W1 < 13λ or W1 < 11λ.

### Surface Acoustic Wave Filter Assemblies

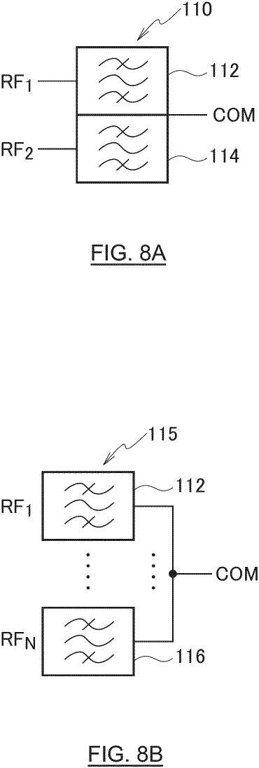

FIG. 8A is a schematic diagram of a duplexer 110 including filters 112 and 114 such as surface acoustic wave filters 1 according to an embodiment shown in FIG. 3. The duplexer 110 includes a first filter 112 and a second filter 114 coupled together at a common node COM. One of the first and second filters 112 and 114 can be a transmit filter and the other can be a receive filter. In some other instances, such as in a diversity receive application, the duplexer 110 can include two receive filters. The common node COM can be an antenna node.

The first filter 112 is a surface acoustic wave filter configured to filter a radio frequency signal. The first filter 112 can include a surface acoustic wave resonator coupled between a first radio frequency node RF1 and the common node COM. The first radio frequency node RF1 can be a transmit node or a receive node. The first filter 112 includes a plurality of surface acoustic wave resonators in accordance with any suitable principles and advantages disclosed herein.

The second filter 114 can be any suitable filter configured to filter a second radio frequency signal. The second filter 114 can be, for example, a surface acoustic wave filter, a film bulk acoustic wave filter, an LC filter, a hybrid acoustic wave LC filter, or the like. The second filter 114 is coupled between a second radio frequency node RF2 and the common node COM. The second radio frequency node RF2 can be a transmit node or a receive node.

Although example embodiments may be discussed with filters or duplexers for illustrative purposes, any suitable principles and advantages disclosed herein can be implemented in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like.

FIG. 8B is a schematic diagram of a multiplexer 115 including a plurality of filters 112 to 116, which include a surface acoustic wave filter 1 according to an embodiment shown in FIG. 3. The multiplexer 115 includes a plurality of filters 112 to 116 coupled together at a common node COM. The plurality of filters 112 to 116 can include any suitable number of filters. For instance, the plurality of filters can include three filters, four filters, five filters, six filters, seven filters, eight filters, or more or less number of filters. Some or all of the plurality of acoustic wave filters can be surface acoustic wave filters.

The first filter 112 is a surface acoustic wave filter configured to filter a radio frequency signal. The surface acoustic wave filter is coupled between a first radio frequency node RF1 and the common node COM. The first radio frequency node RF1 can be a transmit node or a receive node. The first filter 112 includes a plurality of surface acoustic wave resonators in accordance with any suitable principles and advantages disclosed herein. The other filter(s) of the multiplexer 115 can include one or more surface acoustic wave resonators, one or more film bulk acoustic wave filters that include a plurality of surface acoustic wave resonators implemented in accordance with any suitable principles and advantages disclosed herein, one or more LC filters, one or more hybrid acoustic wave LC filters, or any suitable combination thereof.

The acoustic wave resonators discussed herein can be implemented in a variety of packaged modules. Some example packaged modules will now be discussed in which any suitable principles and advantages of the acoustic wave filters and/or acoustic wave resonators discussed herein can be implemented. Example packaged modules may include a package that encloses the illustrated circuit elements. A module including a radio frequency component can be referred to as a radio frequency module. The illustrated circuit elements can be disposed on a common package substrate. The package substrate can be a laminate substrate, for example.

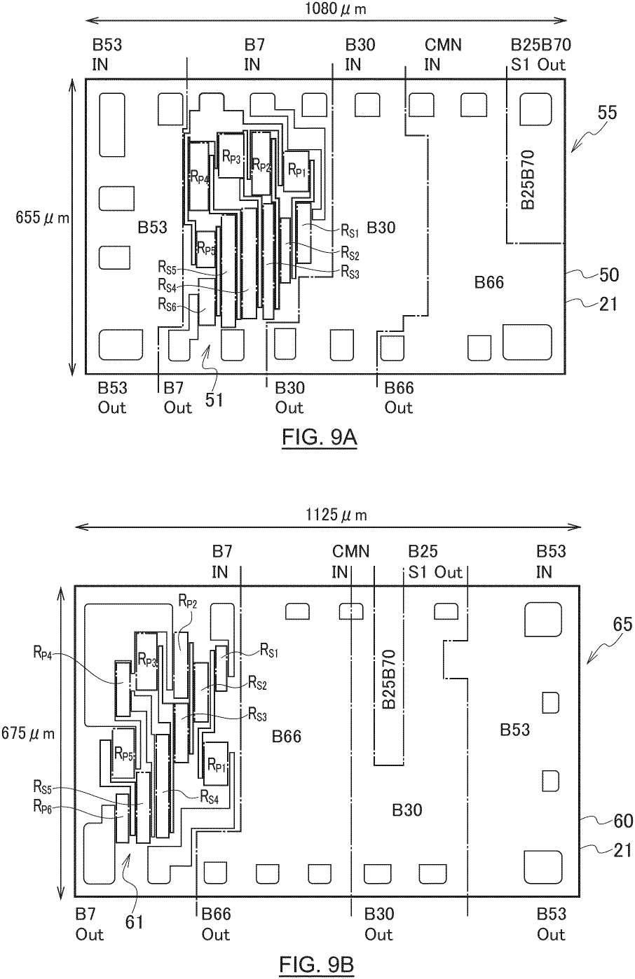

FIG. 9A is a plan view of a multi-band surface acoustic wave filter according to an embodiment. The multi-band surface acoustic wave filter 55 is arranged on a single chip 50 to include a plurality of filters of the multiplexer 115 shown in FIG. 8B. Specifically, the multi-band surface acoustic wave filter 5 includes six filters arranged on a common substrate 21 of the chip 50. The six filters include a band 7 (B7) surface acoustic wave filter 51 of long term evolution (LTE) having a ladder-type structure shown in FIG. 3, as well as band 25 (B25), band 30 (B30), band 53 (B53), band 66 (B66) and band 70 (B70) surface acoustic wave filters B25, B30, B53, B66 and B70, which are disposed together on the common substrate 21. It should be appreciated that the multi-band surface acoustic wave filter 55 is assumed to be a receive filter configured to have downlinks for the band 7 surface acoustic wave filter 51 and the other surface acoustic wave filters B25, B30, B53, B66 and B70. As shown in FIG. 9A, the surface acoustic wave filters for B53, B7, B30, B66, B25 and B70, which form the multi-band surface acoustic wave filter 55, are arranged sequentially from left to right in the drawing, on a top surface of the substrate 21. In a region for B7, first to sixth series arm surface acoustic wave resonator R_{S1} to R_{S6} and first to fifth parallel arm surface acoustic wave resonators R_{P1} to R_{P5} are coupled to form a ladder-type filter, which is referred to as a B7 surface acoustic wave filter 51 herein. Although the numbers of series arm resonators and parallel arm resonators in the B7 surface acoustic wave filter 51 are different from the numbers of series arm resonators and parallel arm resonators in the surface acoustic wave filter 1 shown in FIG. 3, the B7 surface acoustic wave filter 51 and the surface acoustic wave filter 1 both have a similar ladder-type structure. All or some of the other surface acoustic wave filters for B25, B30, B53, B66 and B70 can form a ladder-type filter circuitry similar to the B7 surface acoustic wave filter 51. As discussed above, a series arm surface acoustic wave resonator according to an embodiment has the aperture W1 of the IDT electrode configured to be less than 13λ. The chip 50 of the multi-band surface acoustic wave filter 55 shown in FIG. 9A was configured in a rectangular shape having a longitudinal dimension of 1080 µm and a lateral dimension of 655 µm

FIG. 9B is a plan view of a multi-band surface acoustic wave filter 65 according to a comparative example. The multi-band surface acoustic wave filter 65 of the comparative example includes six filters arranged on a common substrate 21 of the chip 60 similar to the multi-band surface acoustic wave filter 65 shown in FIG. 9A according to an embodiment. The six filters include a band 7 (B7) surface acoustic wave filter 61 of LTE having a ladder-type structure shown in FIG. 3, as well as band 25 (B25), band 30 (B30), band 53 (B53), band 66 (B66) and band 70 (B70) surface acoustic wave filters B25, B30, B53, B66 and B70, which are disposed together on the common substrate 21. However, the multi-band surface acoustic wave filter 65 of the comparative example has the aperture W1 of series arm surface acoustic wave resonators forming each surface acoustic wave filter configured to be 13λ or greater, as discussed with reference to FIG. 2B. For example, the B7 surface acoustic wave filter 65 is configured such that the aperture W1 of the first series arm surface acoustic wave resonator R_{S1} can be 16.5λ, the aperture W1 of the second series arm surface acoustic wave resonator R_{S2} can be 13.5λ, the aperture W1 of the third series arm surface acoustic wave resonator R_{S3} can be 15.3λ, and the aperture W1 of the fourth series arm surface acoustic wave resonator R_{S4} can be 19.5λ, as discussed with reference to FIGS. 4D, 5D, 6D and 7D for the comparative examples. The chip 60 of the multi-band surface acoustic wave filter 65 of the comparative example shown in FIG. 9B was configured in a rectangular shape having a longitudinal dimension of 1125 µm and a lateral dimension of 675 µm.

Comparing the multi-band surface acoustic wave filter 55 of an embodiment shown in FIG. 9A with the multi-band surface acoustic wave filter 65 of the comparative example shown in FIG. 9B, the chip 50 of the multi-band surface acoustic wave filter 55 was configured to have an area of 1080 µm x 655 µm whereas the chip 60 of the multi-band surface acoustic wave filter 65 was configured to have an area of 1125 µm x 675 µm as described above, and accordingly the area of the chip 50 was reduced by substantially 7 % from the area of the chip 60. Thus, according to an embodiment, the multi-band surface acoustic wave filter 55 was confirmed to downsize the chip 50 configuring the circuitry. Further, such a downsizing can allow a signal path between an input node B7IN and an output node B7OUT to be shortened in the B7 surface acoustic wave filter 51 forming the multi-band surface acoustic wave filter 55, and the insertion loss can be improved. The same is applicable to another surface acoustic wave filter forming the multi-band acoustic wave filter 55.

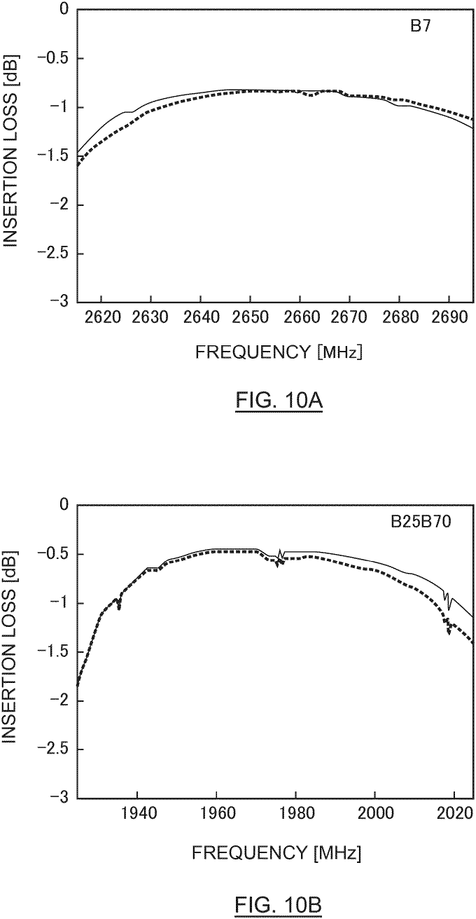

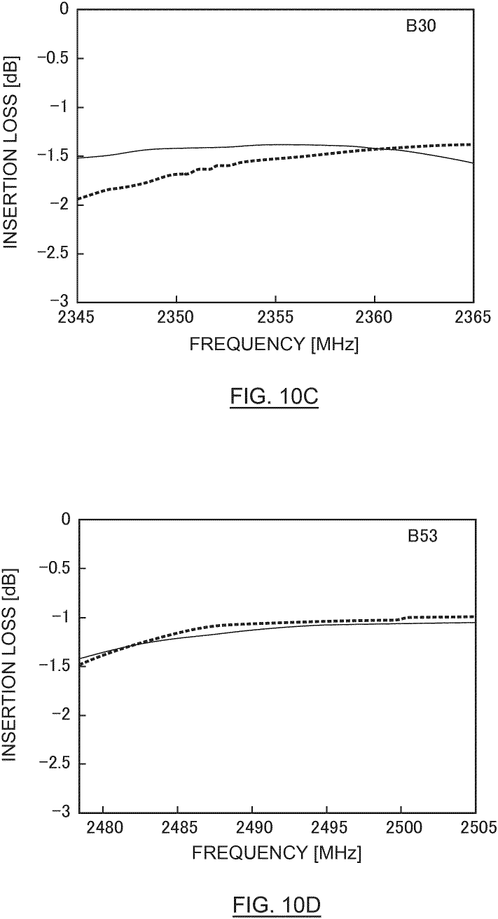

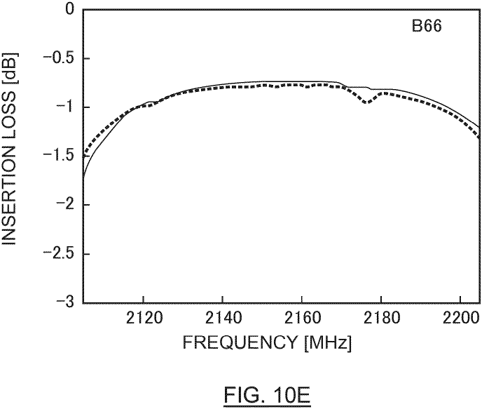

FIGS. 10A to 10E are graphs showing examples of insertion loss versus frequency of the multi-band surface acoustic wave filter 55 shown in FIG. 9A according to an embodiment and the multi-band surface acoustic wave filter 65 shown in FIG. 9B according to a comparative example. The insertion losses are obtained by evaluating maximum gains for the respective multi-band surface acoustic wave filter 55 and 65 in simulations. In each of FIGS. 10A to 10E, a solid line corresponds to the multi-band surface acoustic wave filter 55 shown in FIG. 9A according to an embodiment, and a dashed line corresponds to the multi-band surface acoustic wave filter 65 shown in FIG. 9B according to a comparative example. FIG. 10A is a graph showing an example of insertion loss versus frequency in a downlink band frequency 2620 MHz to 2690 MHz of Band 7 (B7) for LTE. FIG. 10B is a graph showing an example of insertion loss versus frequency in downlink band frequencies 1930 MHz to 1995 MHz and 1995 MHz to 2020 MHz of Bands 25 and 70 (B25B70). FIG. 10C is a graph showing an example of insertion loss versus frequency in a downlink band frequency 2350 MHz to 2360 MHz of Band 30 (B30). FIG. 10D is a graph showing an example of insertion loss versus frequency in a downlink band frequency 2483.5 MHz to 2495 MHz of Band 53 (B53). FIG. 10E is a graph showing an example of insertion loss versus frequency in a downlink band frequency 2110 MHz to 2200 MHz of Band 66 (B66). In any one of the band frequencies shown in FIGS. 10A to 10E, the insertion loss of the multi-band surface acoustic wave filter 55 according to an embodiment was observed to have a preferable frequency characteristic similar to the insertion loss of the multi-band surface acoustic wave filter 65 according to a comparative example.

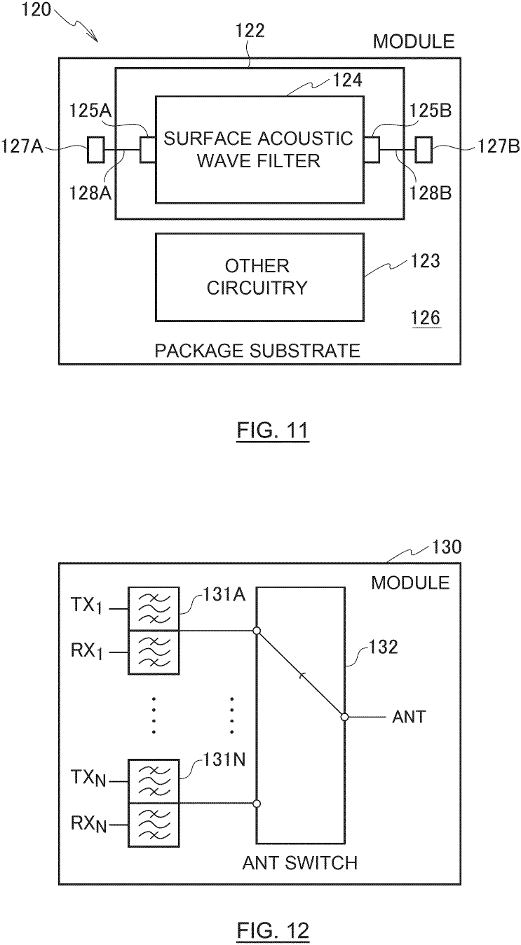

FIGS. 11 to 14 are schematic block diagrams of illustrative packaged modules 120, 130, 140, 150 according to certain embodiments. Any suitable combination of features of these packaged modules 120, 130, 140, 150 can be implemented with each other. While duplexers are illustrated in the example packaged modules 120, 130, 140, 150 of FIGS. 11 to 14, any other suitable multiplexer that includes a plurality of filters coupled to a common node can be implemented instead of one or more duplexers. For instance, a quadplexer can be implemented in certain applications. Alternatively or additionally, one or more filters of a packaged module 120, 130, 140, 150 can be configured as a transmit filter or a receive filter that is not included in a multiplexer.

FIG. 11 is a schematic diagram of a radio frequency module 120 that includes a surface acoustic wave component 122 according to an embodiment. The example radio frequency module 120 includes a surface acoustic wave component 122 and other circuitry 123. The surface acoustic wave component 122 can include one or more surface acoustic wave filters in accordance with any suitable combination of features disclosed herein. The surface acoustic wave component 122 can include a surface acoustic wave resonator die including surface acoustic wave resonators, for example.

The surface acoustic wave component 122 illustrated in FIG. 11 includes one or more surface acoustic wave filters 124, and terminals 125A and 125B. The one or more surface acoustic wave filters 124 include one or more surface acoustic wave resonators implemented in accordance with any suitable principles and advantages disclosed herein. The terminals 125A and 125B can serve, for example, as an input contact and an output contact. Although two terminals are illustrated, any suitable number of terminals can be implemented for a particular application. The surface acoustic wave component 122 and the other circuitry 123 are on a common package substrate 126 in FIG. 11. The package substrate 126 can be a laminate substrate. The terminals 125A and 125B can be electrically connected to contacts 127A and 127B, respectively, on the package substrate 126 by way of electrical connectors 128A and 128B, respectively. The electrical connectors 128A and 128B can be bumps or wire bonds, for example.

The other circuitry 123 can include any suitable additional circuitry. For example, the other circuitry 123 can include one or more power amplifiers, one or more radio frequency switches, one or more additional filters, one or more low noise amplifiers, one or more RF couplers, one or more delay lines, one or more phase shifters, the like, or any suitable combination thereof. The other circuitry 123 is electrically connected to the one or more surface acoustic wave filter 124. The radio frequency module 120 can include one or more packaging structures to, for example, provide protection and/or facilitate easier handling of the radio frequency module 120. Such a packaging structure can include an overmold structure formed over the package substrate 126. The overmold structure can encapsulate some or all of the components of the radio frequency module 120.

FIG. 12 is a schematic block diagram of a radio frequency module 130 that includes duplexers 131A to 131N and an antenna switch 132. One or more filters of the duplexers 131A to 131N can include two or more acoustic wave resonators having resonant frequencies in accordance with any suitable principles and advantages disclosed herein. Any suitable number of duplexers 131A to 131N can be implemented. The antenna switch 132 can have a number of throws corresponding to the number of duplexers 131A to 131N. The antenna switch 132 can include one or more additional throws coupled to one or more filters external to the radio frequency module 130 and/or coupled to other circuitry. The antenna switch 132 can electrically couple a selected duplexer to an antenna port of the radio frequency module 130.

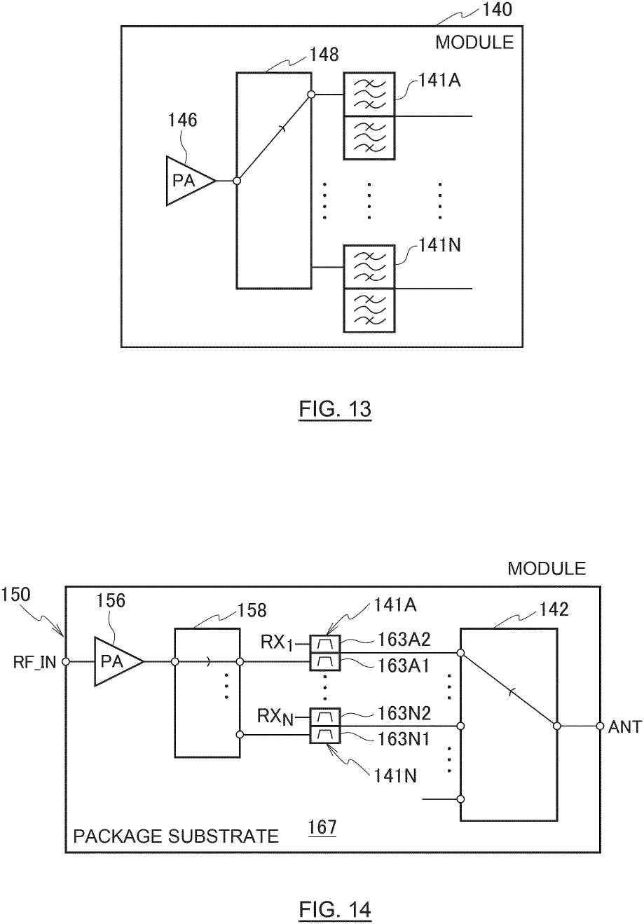

FIG. 13 is a schematic block diagram of a radio frequency module 140 that includes a power amplifier 146, a radio frequency switch 148, and duplexers 141A to 141N according to an embodiment. The power amplifier 146 can amplify a radio frequency signal. The radio frequency switch 148 can be a multi-throw radio frequency switch. The radio frequency switch 148 can electrically couple an output of the power amplifier 146 to a selected transmit filter of the duplexers 141A to 141N. One or more filters of the duplexers 141A to 141N can include any suitable number of surface acoustic wave resonators implemented in accordance with any suitable principles and advantages disclosed herein. Any suitable number of duplexers 141A to 141N can be implemented.

FIG. 14 is a schematic diagram of a radio frequency module 150 that includes a surface acoustic wave filter according to an embodiment. As illustrated, the radio frequency module 150 includes duplexers 141A to 141N that include respective transmit filters 163A1 to 163N1 and respective receive filters 163A2 to 163N2, a power amplifier 156, a select switch 158, and an antenna switch 142. The radio frequency module 150 can include a package that encloses the illustrated elements. The illustrated elements can be disposed on a common package substrate 167. The package substrate 167 can be a laminate substrate, for example. The radio frequency module 150 that includes a power amplifier 156 can be referred to as a power amplifier module. The radio frequency module 150 can include a subset of the elements illustrated in FIG. 13 and/or additional elements. The radio frequency module 150 can include at least one surface acoustic wave device implemented in accordance with any suitable principles and advantages disclosed herein.

The duplexers 141A to 141N can each include two surface acoustic wave filters coupled to a common node. For instance, the two surface acoustic wave filters can be a transmit filter and a receive filter. As illustrated, the transmit filter and the receive filter can each be a band pass filter arranged to filter a radio frequency signal. One or more of the transmit filters 163A1 to 163N1 can include surface acoustic wave resonators implemented in accordance with any suitable principles and advantages disclosed herein. One or more of the receive filters 163A2 to 163N2 can include surface acoustic wave resonators implemented in accordance with any suitable principles and advantages disclosed herein. Although FIG. 14 illustrates duplexers, any suitable principles and advantages disclosed herein can be implemented in other multiplexers (e.g., quadplexers, hexaplexers, octoplexers, etc.) and/or in switch-plexers.

The power amplifier 156 can amplify a radio frequency signal. cThe illustrated switch 158 is a multi-throw radio frequency switch. The switch 158 can electrically couple an output of the power amplifier 156 to a selected transmit filter of the transmit filters 163A1 to 163N1. In some instances, the switch 158 can electrically connect the output of the power amplifier 156 to more than one of the transmit filters 163A1 to 163N1. The antenna switch 142 can selectively couple a signal from one or more of the duplexers 141A to 141N to an antenna port ANT. The duplexers 141A to 141N can be associated with different frequency bands and/or different modes of operation (e.g., different power modes, different signaling modes, etc.).

### Wireless Communication Devices

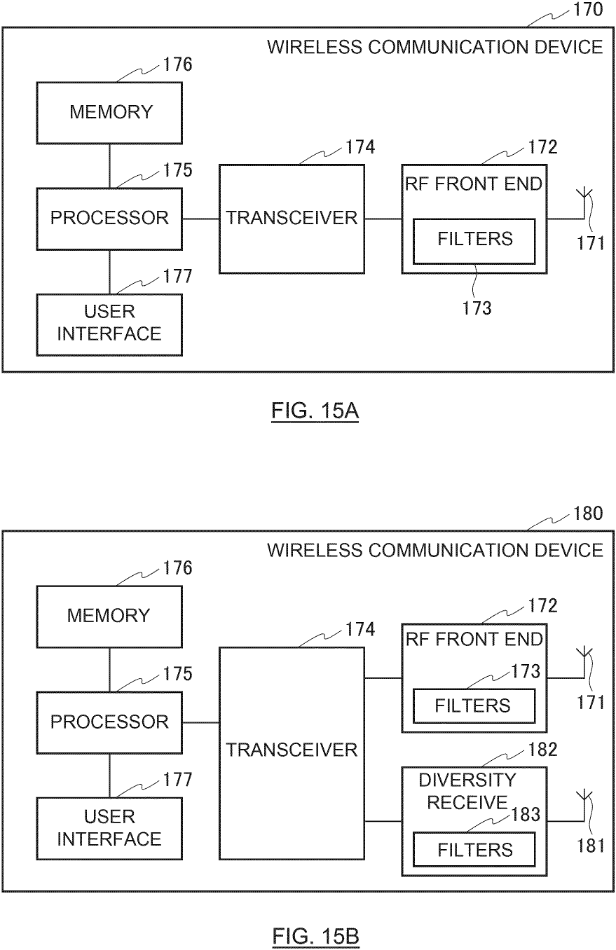

The filters including surface acoustic wave resonators disclosed herein can be implemented in a variety of wireless communication devices. FIG. 15A is a schematic diagram of a wireless communication device 170 that includes filters 173 in a radio frequency (RF) front end 172 according to an embodiment. One or more of the filters 173 can include surface acoustic wave resonators implemented in accordance with any suitable principles and advantages disclosed herein. The wireless communication device 170 can be any suitable wireless communication device. For instance, a wireless communication device 170 can be a mobile phone such as a smart phone. As illustrated, the wireless communication device 170 includes an antenna 171, an RF front end 172, a transceiver 174, a processor 175, a memory 176, and a user interface 177. The antenna 171 can transmit RF signals provided by the RF front end 172. Such RF signals can include carrier aggregation signals. The antenna 171 can receive RF signals and provide the received RF signals to the RF front end 172 for processing. Such RF signals can include carrier aggregation signals. The wireless communication device 170 can include two or more antennas in certain instances.

The RF front end 172 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 172 can transmit and receive RF signals associated with any suitable communication standards. One or more of the filters 173 can include surface acoustic wave resonators that include any suitable combination of features of the embodiments disclosed above.

The transceiver 174 can provide RF signals to the RF front end 172 for amplification and/or other processing. The transceiver 174 can also process an RF signal provided by a low noise amplifier of the RF front end 172. The transceiver 174 is in communication with the processor 175. The processor 175 can be a baseband processor. The processor 175 can provide any suitable baseband processing functions for the wireless communication device 170. The memory 176 can be accessed by the processor 175. The memory 176 can store any suitable data for the wireless communication device 170. The user interface 177 can be any suitable user interface, such as a display with touch screen capabilities.

FIG. 15B is a schematic diagram of a wireless communication device 180 that includes filters 173 in a radio frequency front end 172 and second filters 183 in a diversity receive module 182. The wireless communication device 180 is like the wireless communication device 170 of FIG. 15A, except that the wireless communication device 180 also includes diversity receive features. As illustrated in FIG. 15B, the wireless communication device 180 includes a diversity antenna 181, a diversity receive module 182 configured to process signals received by the diversity antenna 181 and including the second filters 183, and a transceiver 174 in communication with both the radio frequency front end 172 and the diversity receive module 182. One or more of the second filters 183 can include surface acoustic wave resonators implemented in accordance with any suitable principles and advantages disclosed herein.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 450 MHz to 8.5 GHz. Acoustic wave filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexers, devices, modules, wireless communication devices, apparatus, methods, and systems described herein may be embodied in a variety of other forms. Furthermore, various omissions, substitutions and changes in the form of the resonators, filters, multiplexers, devices, modules, wireless communication devices, apparatus, methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave resonator comprising:
a piezoelectric substrate; and
an interdigital transducer electrode disposed on the piezoelectric substrate, an aperture of the interdigital transducer electrode being configured to be less than 13λ, λ, being a wavelength of a surface acoustic wave excited by the interdigital transducer electrode.

2. The surface acoustic wave resonator of claim 1 wherein the aperture is configured to be less than 11λ.

3. The surface acoustic wave resonator of claim 1 wherein the aperture is configured to be greater than 4λ.

4. The surface acoustic wave resonator of claim 3 wherein the aperture is configured to be greater than 6λ.

5. The surface acoustic wave resonator of claim 1 wherein the interdigital transducer electrode excites the surface acoustic wave having the wavelength λ, on the piezoelectric substrate in a piston mode.

6. A ladder-type acoustic wave filter comprising a plurality of series arm resonators and a plurality of parallel arm resonators, at least one of the plurality of series arm resonators including a piezoelectric substrate and an interdigital transducer electrode disposed on the piezoelectric substrate, an aperture of the interdigital transducer electrode being configured to be less than 13λ, λ, being a wavelength of a surface acoustic wave excited by the interdigital transducer electrode.

7. The ladder type acoustic wave filter of claim 6 wherein the aperture is configured to be less than 11λ.

8. The ladder type acoustic wave filter of claim 6 wherein the aperture is configured to be greater than 4λ.

9. The ladder type acoustic wave filter of claim 8 wherein the aperture is configured to be greater than 6λ.

10. The ladder type acoustic wave filter of claim 6 wherein the interdigital transducer electrode excites the surface acoustic wave having the wavelength λ, on the piezoelectric substrate in a piston mode.

11. A acoustic wave filter assembly comprising:
a first acoustic wave filter connected to a common node; and
a second acoustic wave filter connected to the common node, at least one of the first and second acoustic wave filters being a ladder-type acoustic wave filter including a plurality of series arm resonators and a plurality of parallel arm resonators, at least one of the plurality of series arm resonators including a piezoelectric substrate and an interdigital transducer electrode disposed on the piezoelectric substrate, an aperture of the interdigital transducer electrode being configured to be less than 13λ, λ, being a wavelength of a surface acoustic wave excited by the interdigital transducer electrode.

12. The acoustic wave filter assembly of claim 11 wherein the aperture is configured to be less than 11λ.

13. The acoustic wave filter assembly of claim 11 wherein the aperture is configured to be greater than 4λ.

14. The acoustic wave filter assembly of claim 13 wherein the aperture is configured to be greater than 6λ.

15. The acoustic wave filter assembly of claim 11 wherein the interdigital transducer electrode excites the surface acoustic wave having the wavelength λ, on the piezoelectric substrate in a piston mode.

16. The acoustic wave filter assembly of claim 11 further comprising:
a third acoustic wave filter connected to the common node; and
a fourth acoustic wave filter connected to the common node.

17. A wireless communication device comprising:
an antenna; and
a multiplexer coupled to the antenna, the multiplexer including a plurality of filters coupled to a common node and arranged to filter a radio frequency signal, at least one of the plurality of filters being an acoustic wave filter including a plurality of series arm resonators and a plurality of parallel arm resonators, at least one of the plurality of series arm resonators including a piezoelectric substrate and an interdigital transducer electrode disposed on the piezoelectric substrate, an aperture of the interdigital transducer electrode being configured to be less than 13λ, λ, being a wavelength of a surface acoustic wave excited by the interdigital transducer electrode.

18. The wireless communication device of claim 17 wherein the aperture is configured to be less than 11λ.

19. The wireless communication device of claim 17 wherein the aperture is configured to be greater than 4λ.

20. The wireless communication device of claim 17 wherein the interdigital transducer electrode excites the surface acoustic wave having the wavelength λ, on the piezoelectric substrate in a piston mode.
